(19) United States
(12) Patent Application Publication
(10) Pub. No.: US 2016/0072098 A1
(43) Pub. Date: Mar. 10, 2016

(54) PHOTO-CURING COMPOSITION AND ENCAPSULATED DEVICE COMPRISING SAME

(71) Applicant: SAMSUNG SDI CO., LTD., Giheung-gu, Gyeonggi-do (KR)

(72) Inventors: Chang Min LEE, Uiwang-si, Gyeonggi-do (KR); Se Il OH, Uiwang-si, Gyeonggi-do (KR); Sung Min KO, Uiwang-si, Gyeonggi-do (KR); Ji Hye KWON, Uiwang-si, Gyeonggi-do (KR); Seong Ryong NAM, Uiwang-si, Gyeonggi-do (KR); Yeon Soo LEE, Uiwang-si, Gyeonggi-do (KR); Ji Yeon LEE, Uiwang-si, Gyeonggi-do (KR); Seung Jib CHOI, Uiwang-si, Gyeonggi-do (KR); Kyoung Jin HA, Uiwang-si, Gyeonggi-do (KR)

(21) Appl. No.: 14/785,580

(22) PCT Filed: Oct. 31, 2013
(86) PCT No.: PCT/KR2013/009782

§ 371 Date: Oct. 19, 2015

(30) Foreign Application Priority Data
Apr. 30, 2013 (KR) 10-2013-0048904

(51) Int. Cl. H01L 51/52; H01L 27/32; H01L 51/00; C09K 11/06

(52) U.S. Cl. CPC H01L 51/5256; C09K 11/06; H01L 27/3244; H01L 51/0071; H01L 51/0058; H01L 51/004; C09K 2211/1033; C09K 2211/1011; C09K 2211/1007; H01L 51/56

(57) ABSTRACT

The present invention relates to a photo-curing composition comprising (A) a photo-curable monomer, (B) a light-emitting substance, and (C) an initiator, wherein the light-emitting substance has a maximum light-emitting wavelength of about 400 to 500 nm during irradiation at a wavelength of 300-480 nm, and an encapsulated device comprising the same.

### TECHNICAL FIELD

The present invention relates to a photocurable composition and an encapsulated apparatus including the same.

### BACKGROUND ART

An organic light emitting diode (OLED) has a structure in which a functional organic layer is interposed between a cathode and an anode, and produces highly energetic excitons by recombination of holes injected from the anode with electrons injected from the cathode. The produced excitons are transferred to a ground state to generate light having a specific wavelength.

However, organic light emitting diodes have a problem of deterioration in performance and lifespan due to oxidation of organic materials and/or electrode materials caused by moisture or oxygen from outside or internally or externally generated outgases. To overcome this problem, there have been proposed methods of encapsulating the organic light emitting diode by an organic protective layer formed of an encapsulation composition.

Such an encapsulation process may include forming an organic protective layer, for example, by depositing the encapsulation composition in a vacuum. Here, the encapsulation composition is a liquid and thus can run down to undesired positions other than the organic light emitting diode during deposition, thereby providing defective organic light emitting diodes. Although such a defect can be identified with the naked eye, unfortunately, such visual inspection has poor reliability and requires unnecessary effort.

### DISCLOSURE

### Technical Problem

It is an aspect of the present invention to provide a photocurable composition allowing easy identification as to whether the composition is formed in a desired pattern after curing.

It is another aspect of the present invention to provide a photocurable composition capable of realizing a layer which has high photocuring rate and can avoid a shift due to shrinkage stress after curing.

It is a further aspect of the present invention to provide a photocurable composition capable of realizing a layer which exhibits high adhesion to an inorganic barrier layer and low outgassing after curing.

It is yet another aspect of the present invention to provide an encapsulated apparatus including the photocurable composition as set forth above.

### Technical Solution

In accordance with one aspect of the present invention, a photocurable composition includes (A) a photocurable monomer, (B) a luminescent material, and (C) an initiator, wherein the luminescent material has an emission maximum wavelength of about 400 nm to about 500 nm upon irradiation at a wavelength of 300 nm to 480 nm.

In accordance with another aspect of the present invention, an encapsulated apparatus includes a member for the apparatus and a barrier stack formed on the member for the apparatus and including an inorganic barrier layer and an organic barrier layer, wherein the organic barrier layer may be formed of a cured product of the photocurable composition as set forth above.

### Advantageous Effects

The present invention provides a photocurable composition capable of realizing a layer which has extremely low outgassing after curing and high adhesion to an inorganic barrier layer and thus can prevent performance deterioration of a device and extend lifespan of the device when used to encapsulate the device. In addition, the present invention provides a photocurable composition including a material which does not only exhibit a color under visible light but fluoresces upon UV irradiation, thus allowing easy identification as to whether a deposited or coated barrier layer is properly formed, and enhancing productivity while reducing defect rate.

### DESCRIPTION OF DRAWINGS

FIG. 1 is a sectional view of an encapsulated apparatus according to one embodiment of the present invention.

FIG. 2 is a sectional view of an encapsulated apparatus according to another embodiment of the present invention.

FIGS. 3 to 6 are luminescence spectra of cured products of photocurable compositions of Examples 1 to 4 (where the horizontal axis is wavelength (unit: nm), and the vertical axis is intensity (unit: A.U. (Arbitrary Unit)).

### BEST MODE

As used herein, unless otherwise stated, the term “substituted” means that at least one hydrogen atom among functional groups of the present invention is substituted with a halogen atom (F, Cl, Br or I), a hydroxyl group, a nitro group, a cyano group, an imino group (═NH, ═NR (R: a C₁ to C₁₀ alkyl group)), an amino group (—NH₂, —NH(R′), —N(R″)(R″), where R′, R″ and R′″ are each independently a C₁ to C₁₀ alkyl group), an amidino group, a hydrazine or hydrazone group, a carboxyl group, a substituted or unsubstituted C₁ to C₂₀ alkyl group, a substituted or unsubstituted C₆ to C₃₀ aryl group, a substituted or unsubstituted C₃ to C₃₀ cycloalkyl group, a substituted or unsubstituted C₃ to C₃₀ heteroaryl group, or a substituted or unsubstituted C₂ to C₃₀ heterocycloalkyl group. In addition, as used herein, the term “(meth)acrylate” may refer to acrylate and/or methacrylate.

A photocurable composition according to the present invention may include (A) a photocurable monomer, (B) a luminescent material, and (C) an initiator.

(A) Photocurable Monomer

The photocurable monomer may include a monomer which does not emit light upon UV irradiation, or has an emission maximum wavelength (λ max) of less than 400 nm upon UV irradiation. The photocurable monomer may include a monomer which does not affect luminescence of a luminescent material to be described below even after curing.

The photocurable monomer may include a photocurable functional group-containing monofunctional monomer, a photocurable functional group-containing polyfunctional monomer, or a combination thereof. In some embodiments, the photocurable monomer may include a monomer containing about 1 to about 30 photocurable functional groups, for example about 1 to about 20 photocurable functional groups, for example about 1 to about 6 photocurable functional groups. The photocurable functional group may include a substituted or unsubstituted vinyl group, a substituted or unsubstituted acrylate group, or a substituted or unsubstituted methacrylate group.

The photocurable monomer may include a mixture of a monofunctional monomer and a polyfunctional monomer. In the mixture, the monofunctional monomer and the polyfunctional monomer may be present in a weight ratio of about 1:0.1 to about 1:10, for example, about 1:4 to about 1:6.

The photocurable monomer may include: C₆ to C₂₀ aromatic hydrocarbon compounds containing a substituted or unsubstituted vinyl group; unsaturated carboxylic acid esters containing a C₁ to C₂₀ alkyl group, a C₃ to C₂₀ cycloalkyl group, a C₆ to C₂₀ aromatic group, or a hydroxyl group and a C₁ to C₂₀ alkyl group; C₁ to C₂₀ aminoalkyl group-containing unsaturated carboxylic acid esters; vinyl esters of C₁ to C₂₀ saturated or unsaturated carbonic acids; vinyl cyanide compounds; unsaturated amide compounds; monofunctional or polyfunctional (meth)acrylates of monohydric or polyhydric alcohols, and the like. The term “polyhydric alcohol” refers to alcohols containing two or more, for example, 2 to 20, for example, 2 to 10, for example, 2 to 6 hydroxyl groups.

In some embodiments, the photocurable monomer may include: an C₆ to C₂₀ aromatic hydrocarbon compounds containing alkenyl group including a vinyl group, such as styrene, α-methyl styrene, vinyl toluene, vinyl benzyl ether, and vinyl benzyl methyl ether; unsaturated carboxylic acid esters including (meth)acrylic esters, such as methyl (meth)acrylate, ethyl (meth)acrylate, butyl (meth)acrylate, 2-hydroxyethyl (meth)acrylate, 2-hydroxybutyl (meth)acrylate, hexyl (meth)acrylate, octyl (meth)acrylate, nonyl (meth)acrylate, decanyl (meth)acrylate, undecanyl (meth)acrylate, dodecyl (meth)acrylate, cyclohexyl (meth)acrylate, benzyl (meth)acrylate, phenyl (meth)acrylate, and the like; unsaturated carboxylic acid aminoalkyl esters, such as 2-aminoethyl (meth)acrylate, 2-dimethylaminoethyl (meth)acrylate, and the like; saturated or unsaturated carboxylic acid vinyl esters, such as vinyl acetate, vinyl benzoate, and the like; vinyl cyanide compounds, such as (meth)acrylonitrile; unsaturated amide compounds, such as (meth)acrylamide; and monofunctional or polyfunctional (meth)acrylates of monohydric or polyhydric alcohols including ethylene glycol di(meth)acrylate, triethylene glycol di(meth)acrylate, trimethylolpropane tri(meth)acrylate, 1,4-butanediol di(meth)acrylate, 1,6-hexanediol di(meth)acrylate, octyldiol di(meth)acrylate, nonyldiol di(meth)acrylate, decanyldiol di(meth)acrylate, undecanyldiol di(meth)acrylate, dodecyldiol di(meth)acrylate, neopentyl glycol di(meth)acrylate, pentaerythritol di(meth)acrylate, pentaerythritol tri(meth)acrylate, pentaerythritol tetra(meth)acrylate, dipentaerythritol di(meth)acrylate, dipentaerythritol tri(meth)acrylate, dipentaerythritol tetra(meth)acrylate, dipentaerythritol penta(meth)acrylate, dipentaerythritol hexa(meth)acrylate, bisphenol A di(meth)acrylate, novolac epoxy (meth)acrylate, diethylene glycol di(meth)acrylate, tri(propylene glycol) di(meth)acrylate, polypropylene glycol) di(meth)acrylate, and the like, without being limited thereto.

Preferably, the photocurable monomer includes at least one of C₁ to C₂₀ alkyl group-containing (meth)acrylates, di(meth)acrylates of C₂ to C₂₀ diol, tri(meth)acrylates of C₃ to C₂₀ triol, and tetra(meth)acrylates of C₄ to C₂₀ tetraol.

The photocurable monomer may be present, in terms of solid content, in an amount of about 1 wt % to about 99.99 wt %, for example about 90 wt % to about 99.95 wt %, for example, about 90 wt % to 99.9 wt %, based on the total weight of (A)+(B). Within this range, the photocurable monomer does not affect luminescence of the luminescent material, while increasing photocuring rate, thereby reducing outgassing.

(B) Luminescent Material

The luminescent material may have an emission maximum wavelength (λ max) of about 400 nm to about 500 nm. If λ max is less than 400 nm, the luminescent material is unnoticeable in selection of defective products and thus does not provide a desired effect. If λ max exceeds 500 nm, the composition exhibits a color and is thus not suitable for use as an encapsulation material for displays. For example, the luminescent material may have a λ max of about 400 nm to about 450 nm.

The luminescent material may include a material which has an emission maximum wavelength (λ max) of about 400 nm to about 500 nm upon irradiation at a wavelength of 300 nm to 480 nm (for example, irradiation using a xenon lamp).

The luminescent material allows easy identification as to whether the photocurable composition is formed at a desired position. In other words, the luminescent material has an emission maximum wavelength (λ max) of about 400 nm to about 500 nm upon irradiation at a wavelength of 300 nm to 480 nm and emits fluorescent light, whereby a position at which the photocurable composition is formed (deposited) can be easily identified with the naked eye.

The luminescent material may include at least one of a non-curable compound containing no photocurable functional group and a curable compound containing a photocurable functional group.

In some embodiments, the luminescent material may include at least one of (B1) an organic fluorescent dye having a C.I. Number (color index number) of C.I Fluorescent Brightening Agents 1 to 393 in accordance with the standard of the Society of Dyers and Colourists (SDC), (B2) a substituted or unsubstituted C₁₀ to C₃₀ aromatic hydrocarbon, and (B3) a substituted or unsubstituted C₆ to C₃₀ hetero aromatic hydrocarbon, where the hetero atom may include at least one of nitrogen, oxygen, and sulfur.

The organic fluorescent dye may have a weight average molecular weight of about 170 g/mol to about 1000 g/mol. Within this range, the composition can reduce outgassing and provide sufficient luminescence.

Specifically, the organic fluorescent dye may be represented by any one of Formulas 1-1 to 1-63:

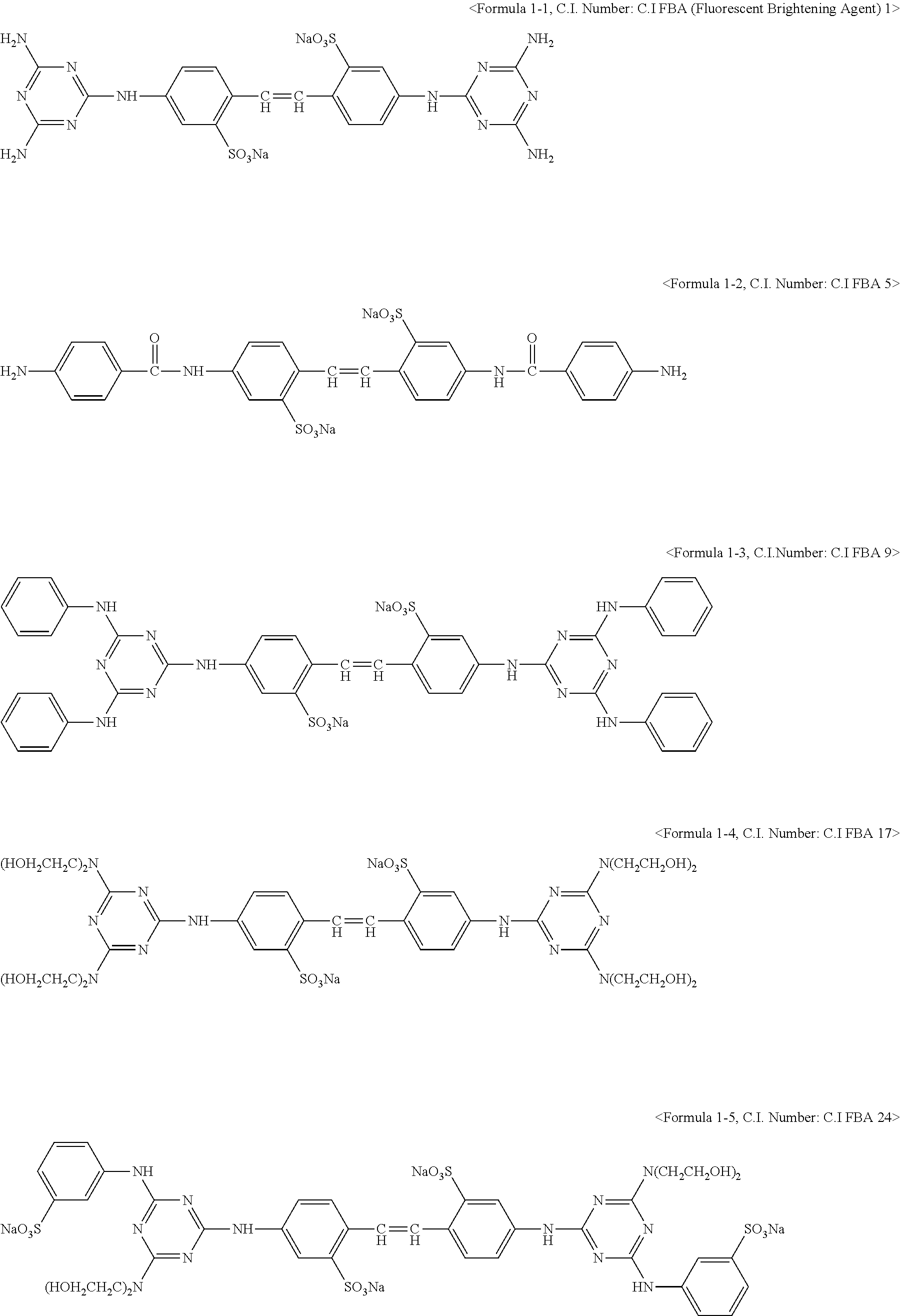

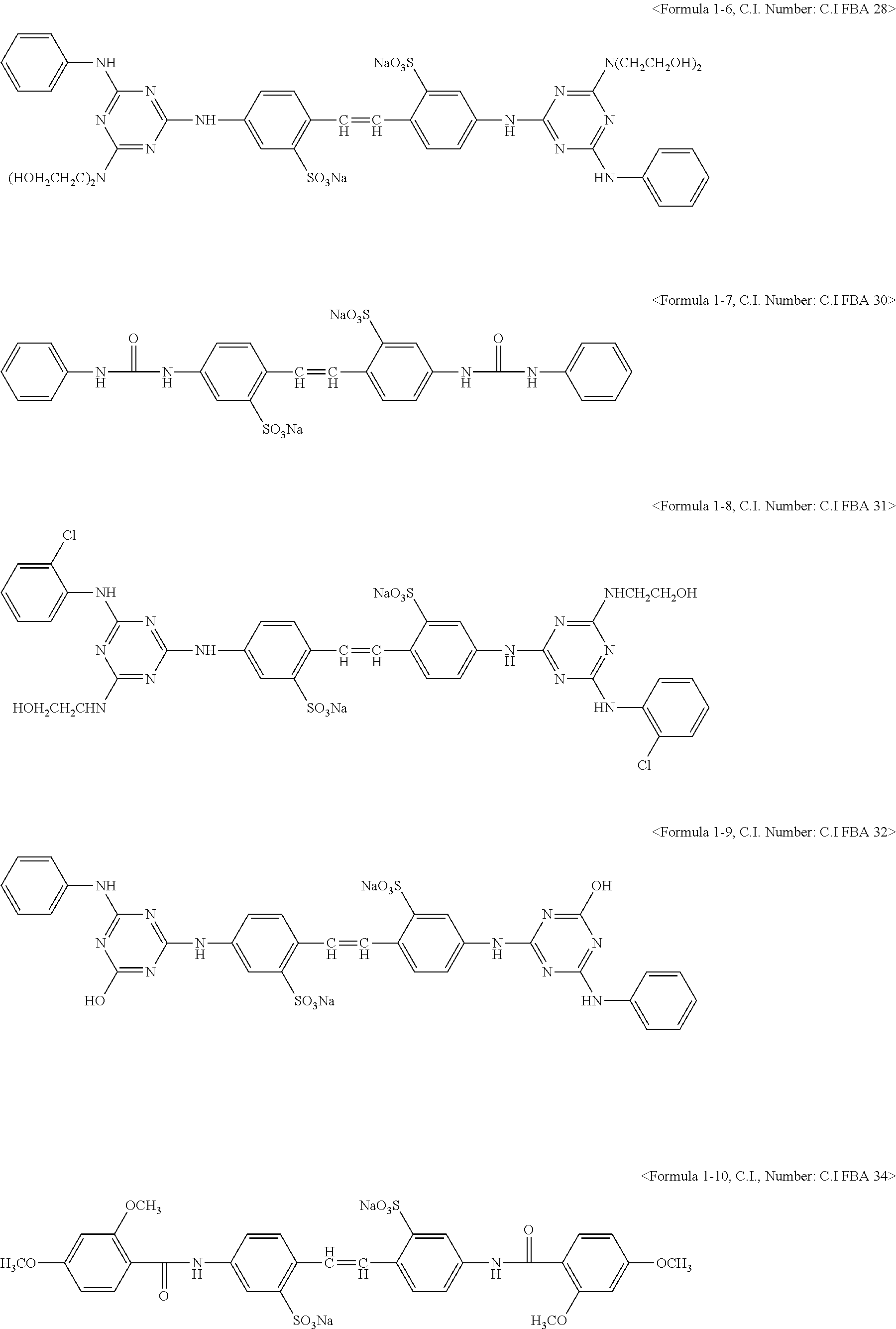

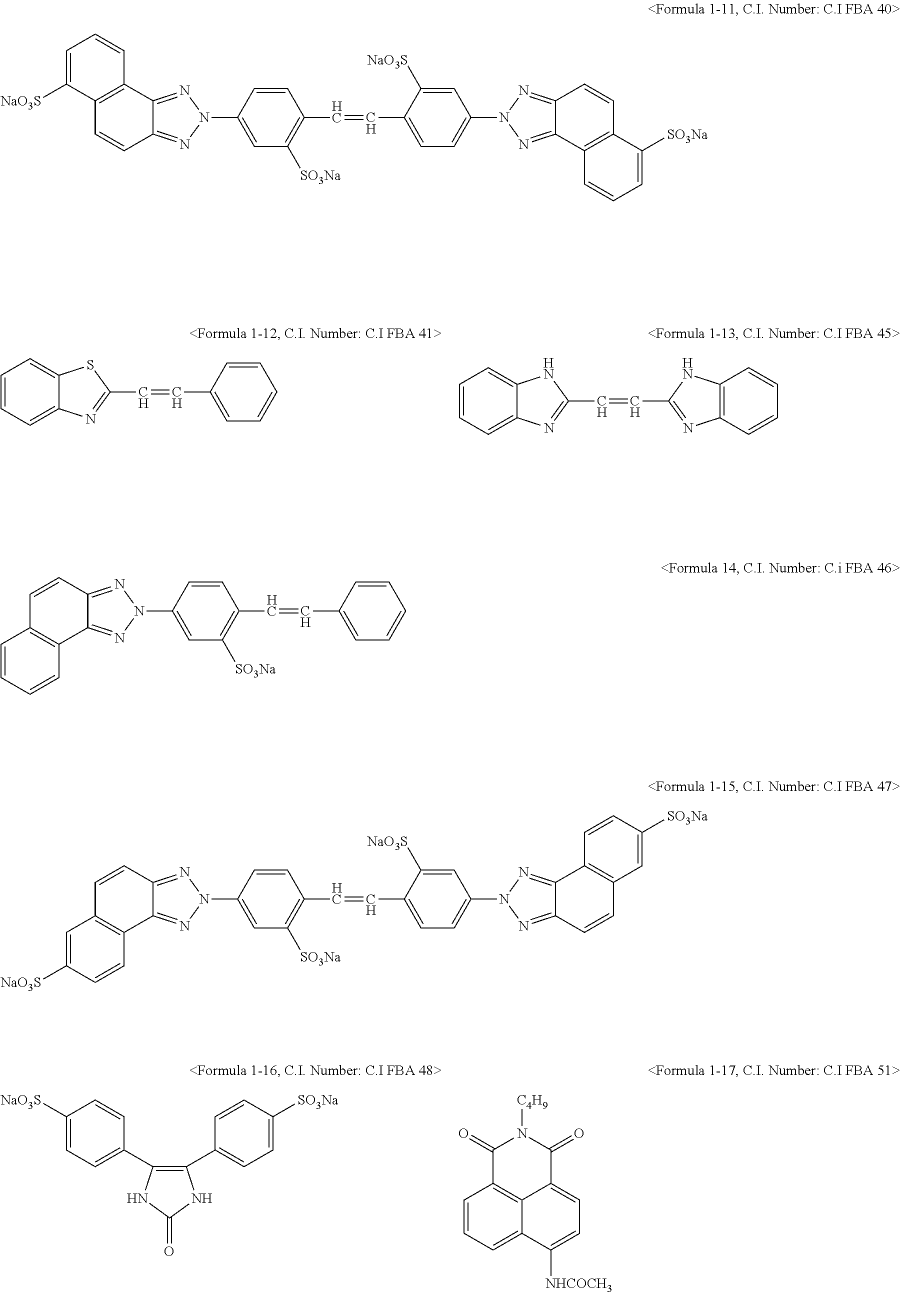

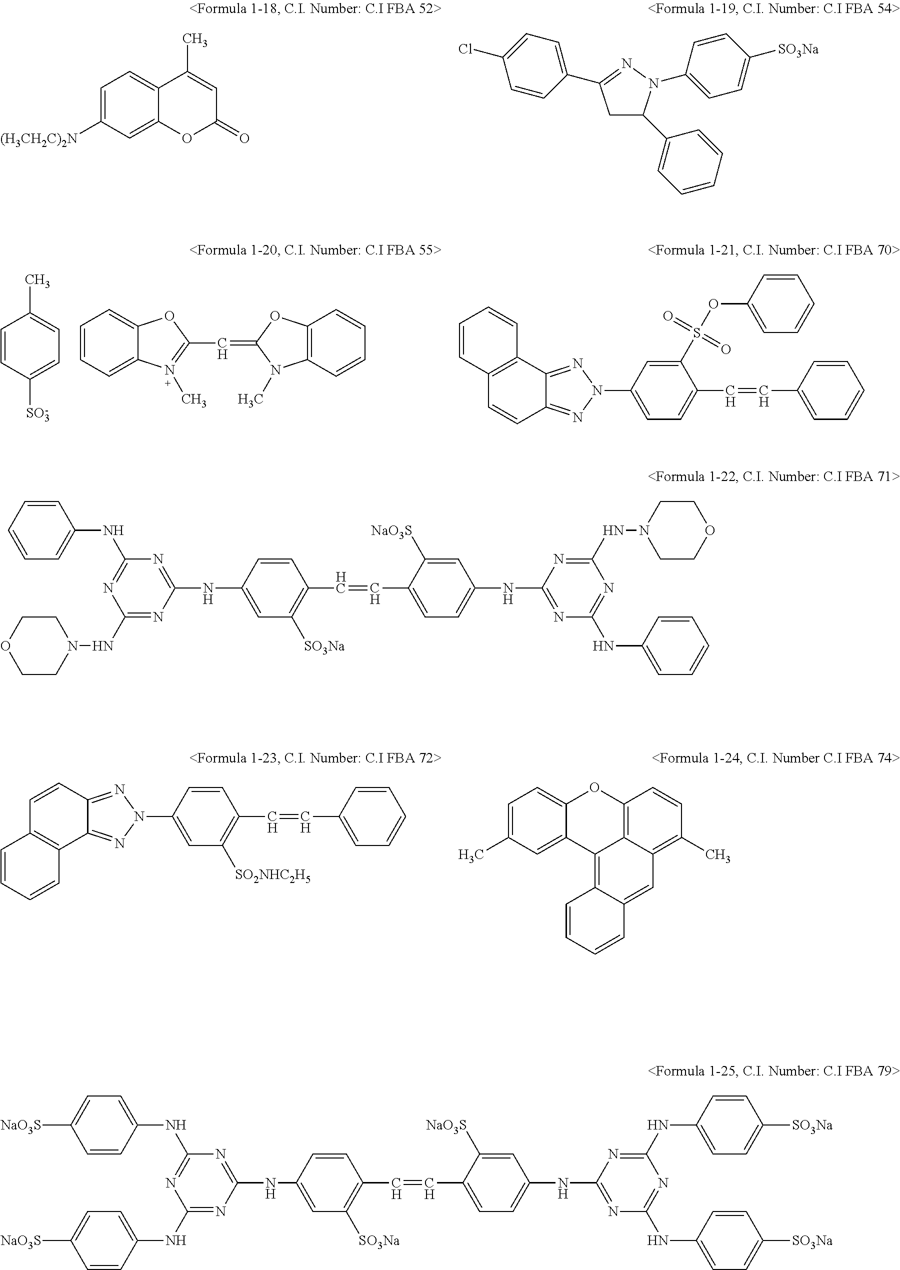

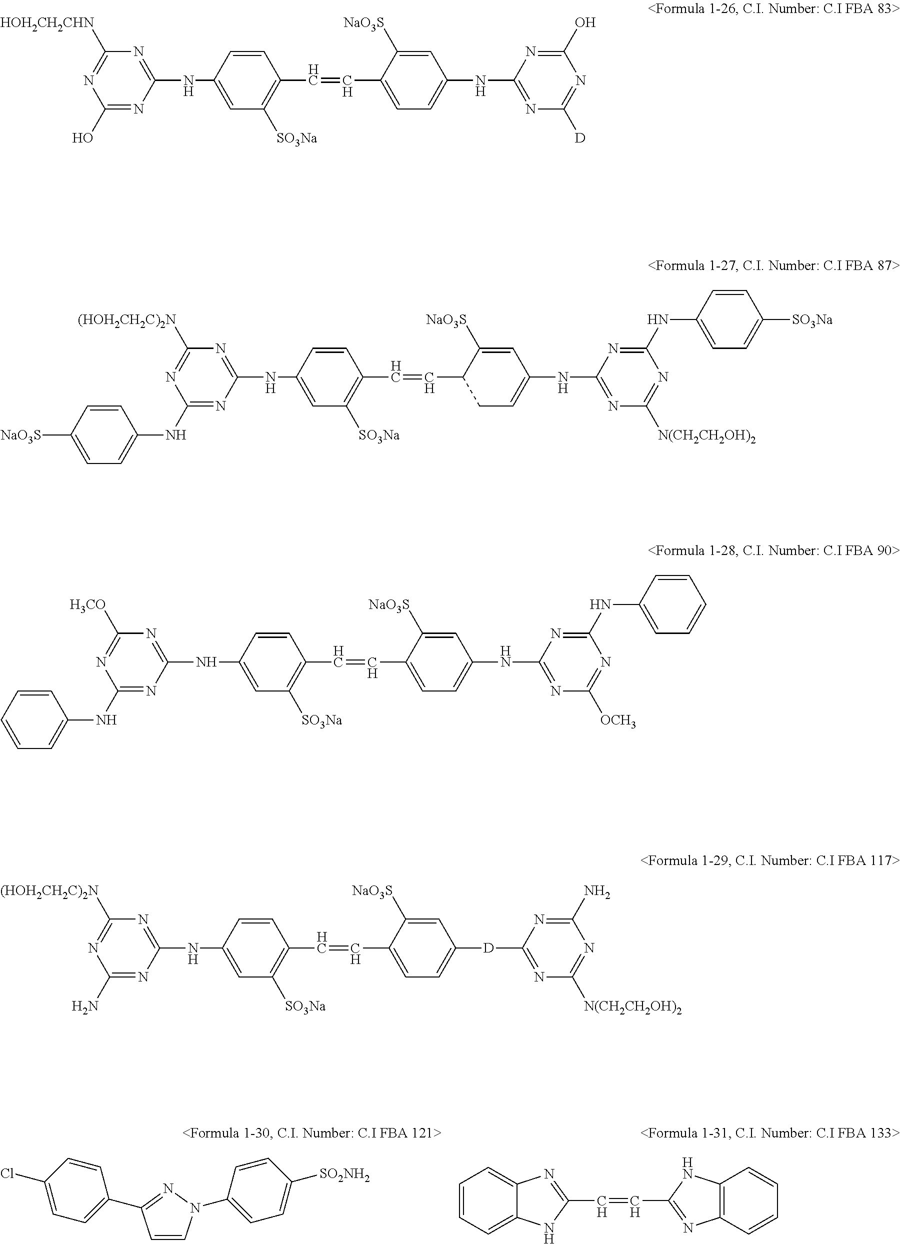

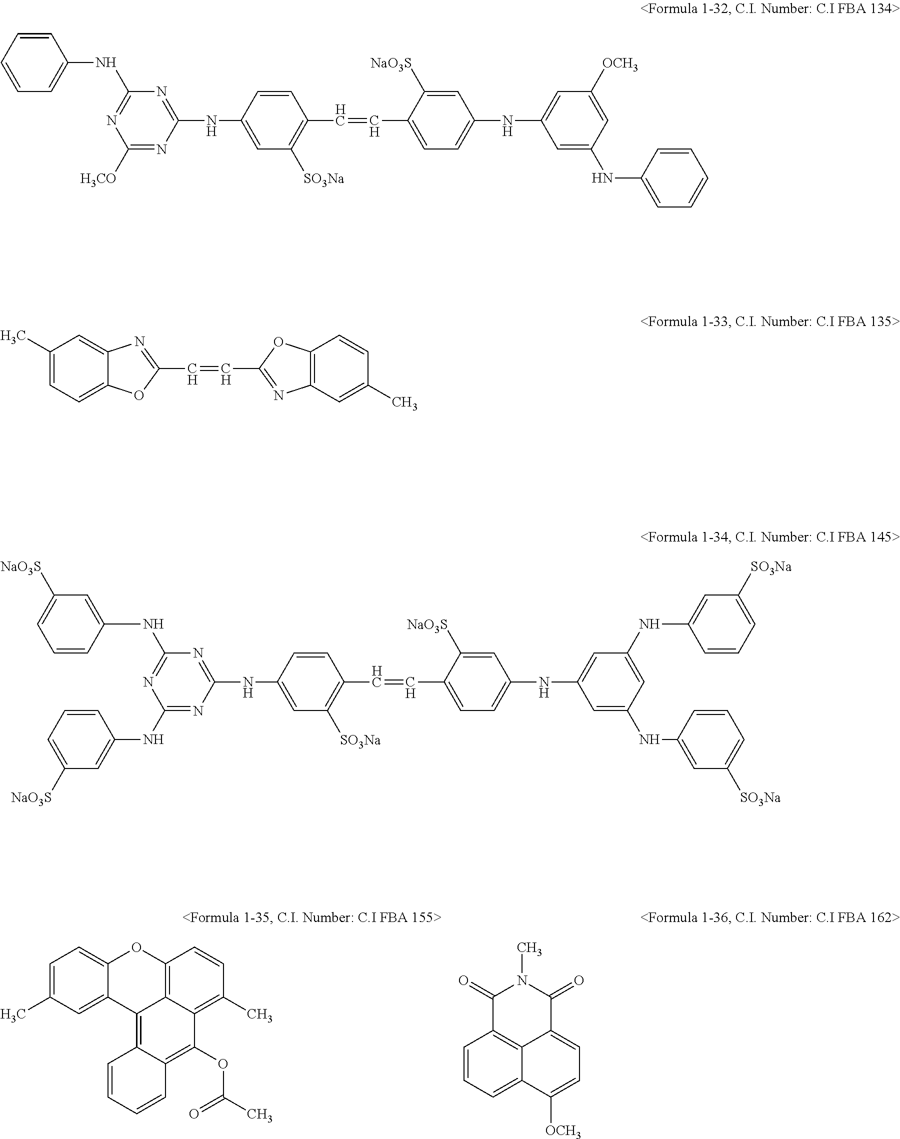

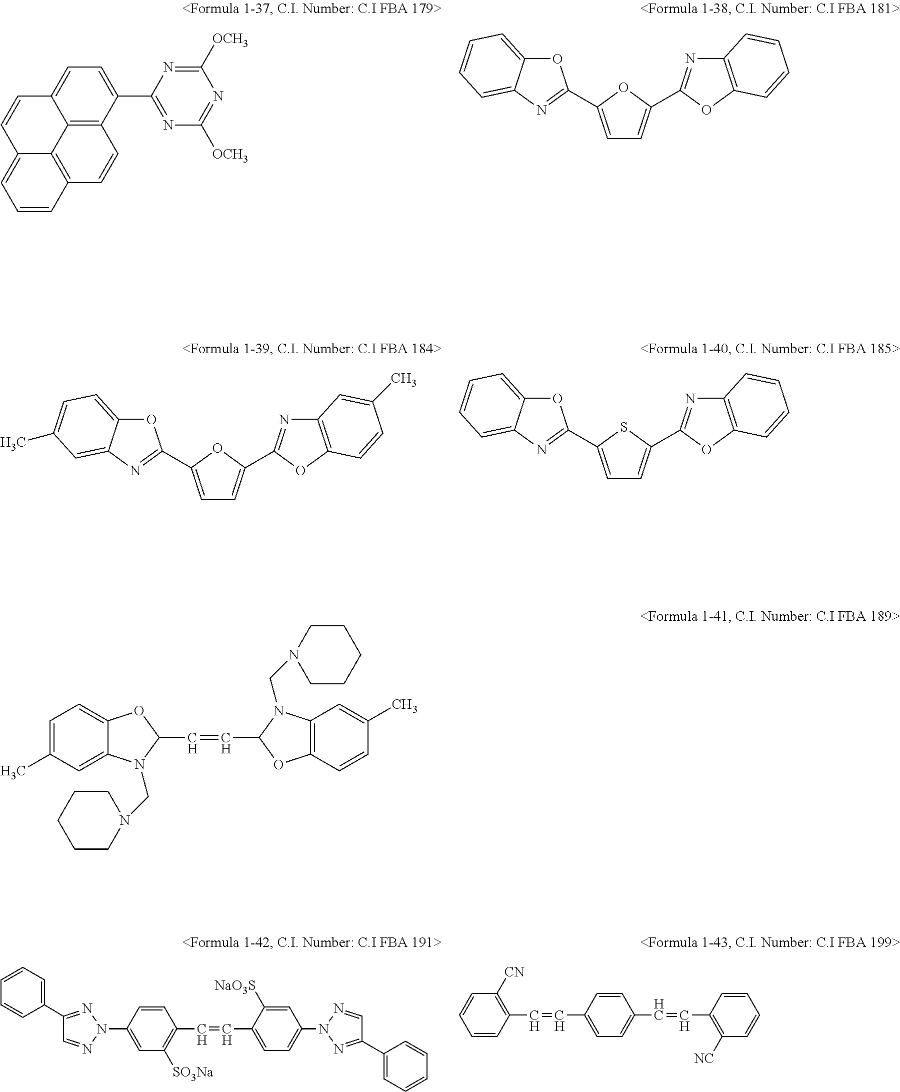

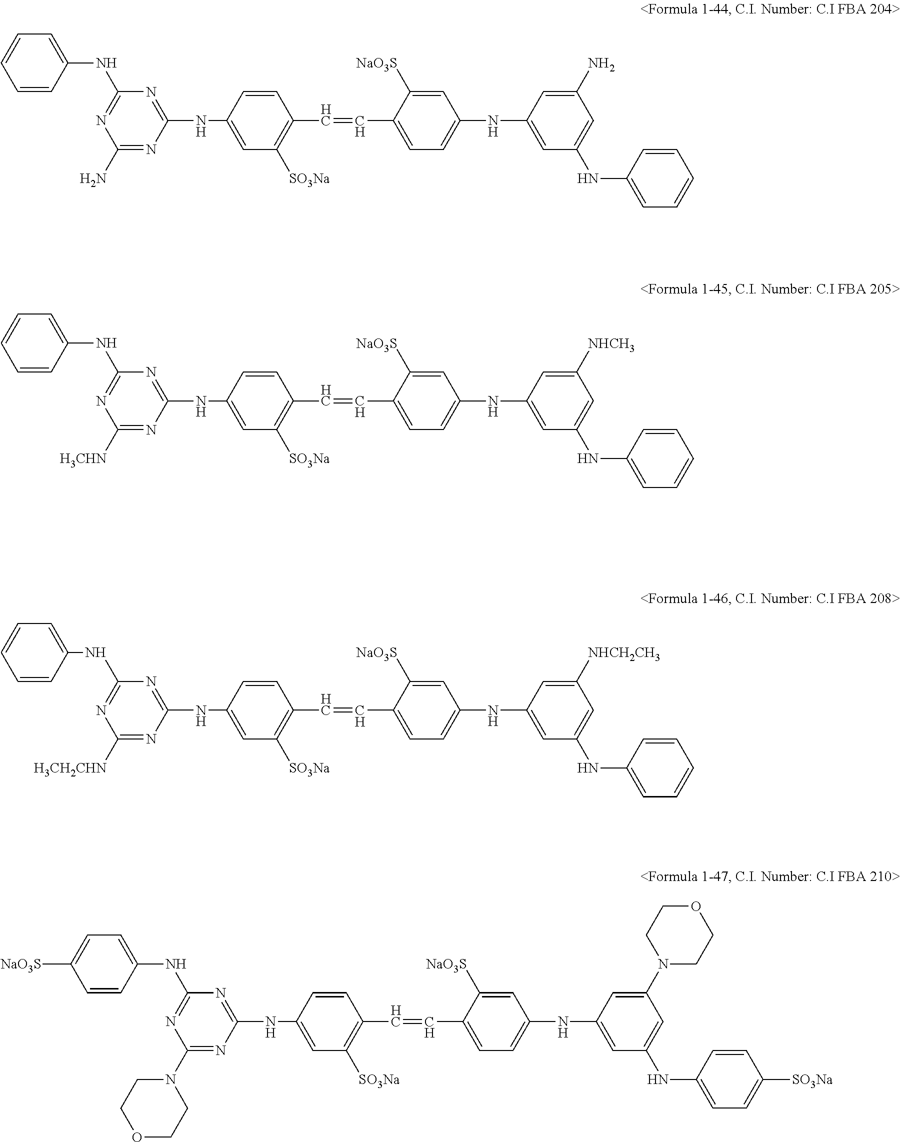

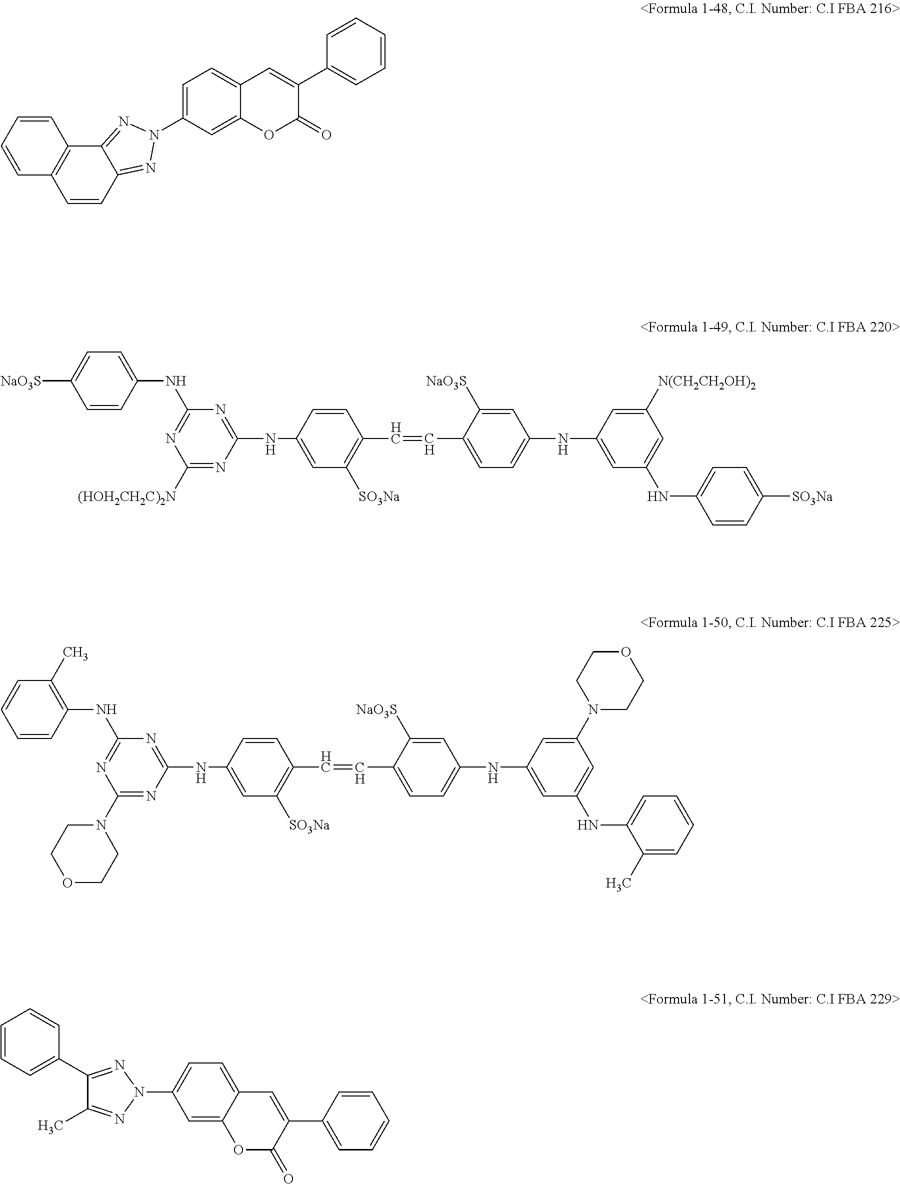

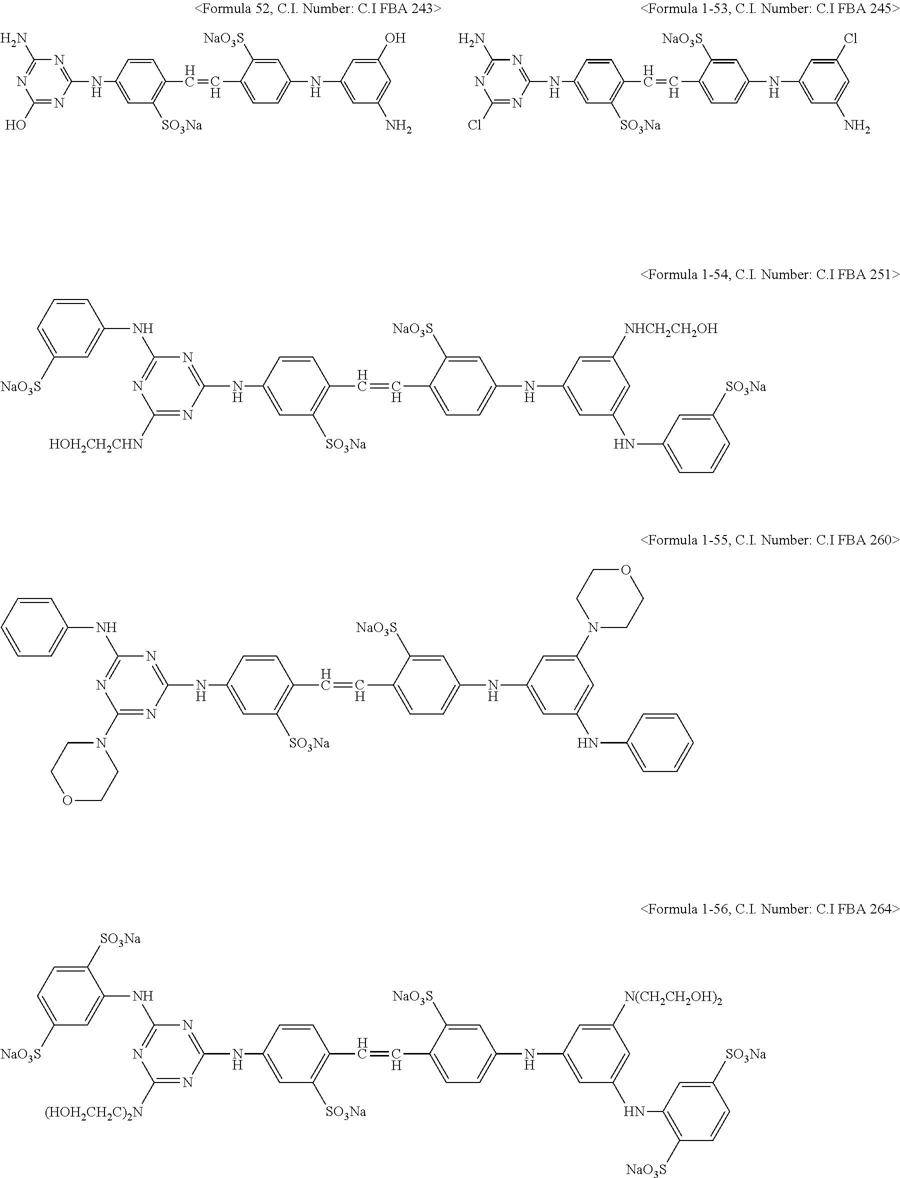

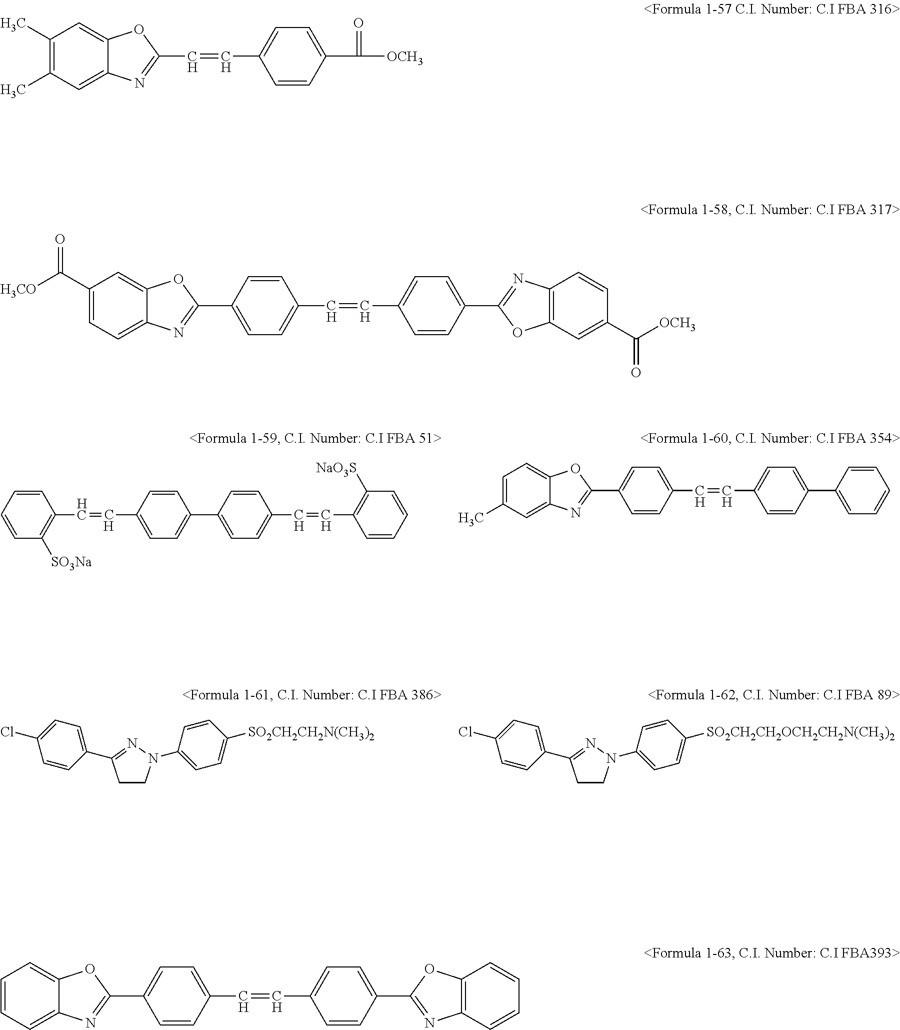

Like the organic fluorescent dye, (B2) and (B3) may have an emission maximum wavelength of about 400 nm to about 500 nm upon irradiation at a wavelength of 300 nm to 480 nm, although having no C.I. Number in accordance with the standard of the Society of Dyers and Colourists (SDC).

The aromatic hydrocarbon is a polycyclic aromatic hydrocarbon and may have a weight average molecular weight of about 170 g/mol to about 1000 g/mol. Within this range, the composition can reduce outgassing and provide sufficient luminescence. In one embodiment, the aromatic hydrocarbon may be represented by Formula 2:

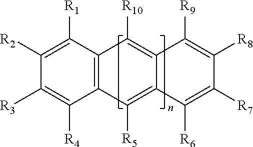

(where in Formula 2, R₁, R₂, R₃, R₄, R₅, R₆, R₇, R₈, R₉, and R₁₀ are each independently hydrogen, a C₁ to C₁₀ alkyl group, a C₆ to C₁₀ aryl group, an amine group, a halogen, a cyano group, a nitro group, Formula 3, Formula 4, Formula 5, or a hydroxyl group-containing C₁ to C₁₀ alkyl group:

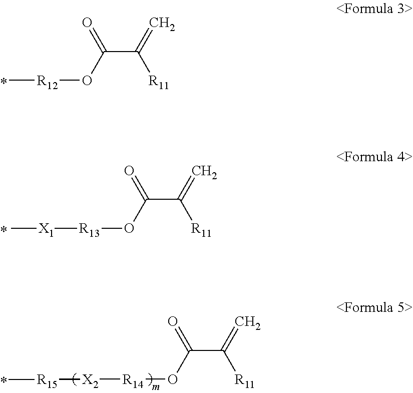

(where in Formula 3 to 5, * is a binding site to aromatic carbon in Formula 2,

R₁₁ is hydrogen or a C₁ to C₅ alkyl group,

R₁₂ is a single bond, a C₁ to C₁₀ alkylene group, or a C₆ to C₂₀ arylene group,

R₁₃, R₁₄, and R₁₅ are each independently a C₁ to C₁₀ alkylene group or a C₆ to C₂₀ arylene group,

X₁ and X₂ are each independently O, S, or NR (R being hydrogen or a C₁ to C₅ alkyl group), and

m is an integer from 1 to 6), and

n is an integer from 1 to 6).

In one embodiment, the aromatic hydrocarbon may be represented by any one of Formula 2-1 to 2-6:

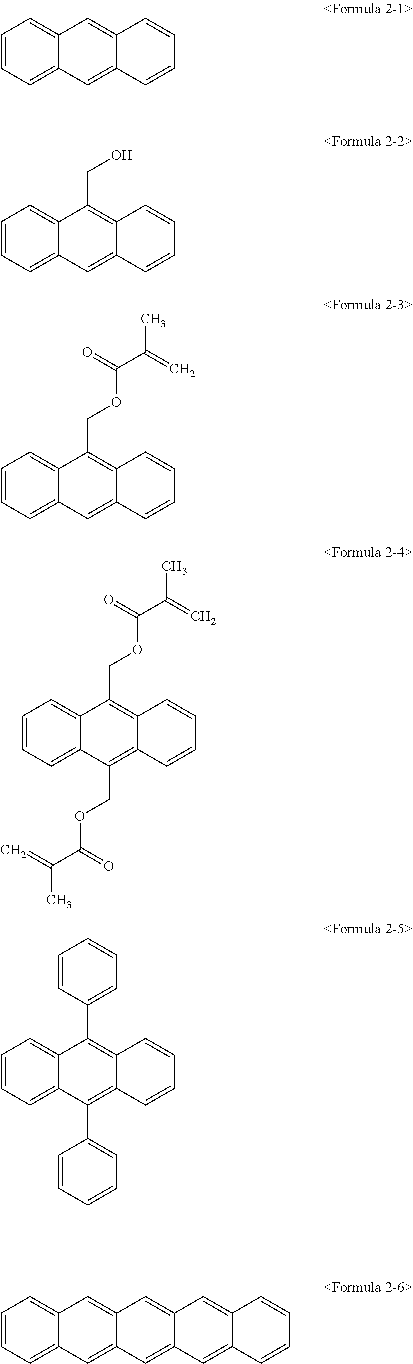

The hetero aromatic hydrocarbon is a hetero atom-containing polycyclic aromatic hydrocarbon and may have a weight average molecular weight of about 170 g/mol to about 1000 g/mol. Within this range, the composition can reduce outgassing and provide sufficient luminescence. In one embodiment, the hetero aromatic hydrocarbon may include, for example, carbazole, without being limited thereto.

The luminescent material may be present in an amount of about 0.01 wt % to about 99 wt % based on the total weight of (A)+(B) in the photocurable composition. Within this range, the composition can emit light without reduction in transmittance, and thus allow easy visual recognition of pattern defects of the composition or a cured product thereof. For example, the luminescent material may be present in an amount of about 0.05 wt % to about 20 wt %, most preferably about 0.05 wt % to about 10 wt %, specifically about 0.1 wt %, 0.5 wt %, 1.0 wt %, 1.5 wt %, 2.0 wt %, 2.5 wt %, 3.0 wt %, 3.5 wt %, 4.0 wt %, 4.5 wt %, 5.0 wt %, 5.5 wt %, 6.0 wt %, 6.5 wt %, 7.0 wt %, 7.5 wt %, 8.0 wt %, 8.5 wt %, 9.0 wt %, 9.5 wt %, or 10.0 wt %.

(C) Initiator

The initiator may include a photopolymerization initiator. The initiator may include an initiator which does not affect luminescence of the luminescent material even after curing of the composition.

The photopolymerization initiator may include any typical photopolymerization initiators capable of performing photocuring reaction in the art. For example, the photopolymerization initiator may include triazine, acetophenone, benzophenone, thioxanthone, benzoin, phosphorus, oxime initiators, and mixtures thereof.

Examples of the triazine initiators may include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2,4-trichloromethyl(piperonyl)-6-triazine, 2,4-(trichloromethyl(4′-methoxy styryl)-6-triazine, and mixtures thereof.

Examples of the acetophenone initiators may include 2,2′-diethoxyacetophenone, 2,2′-dibuthoxyacetophenone, 2-hydroxy-2-methyl propiophenone, p-t-butyl trichloroacetophenone, p-t-butyl dichloroacetophenone, 4-chloroacetophenone, 2,2′-dichloro-4-phenoxyacetophenone, 2-methyl-1-(4-(methylthio)phenyl)-2-morpholinopropan-1-one, 2-benzyl-2-dimethylamino-1-(4-morpholinophenyl)-butan-1-one, and mixtures thereof.

Examples of the benzophenone initiators may include benzophenone, benzoyl benzoate, methyl benzoyl benzoate, 4-phenyl benzophenone, hydroxybenzophenone, acrylated benzophenone, 4,4′-bis(dimethylamino)benzophenone, 4,4′-dichlorobenzophenone, 3,3′-dimethyl-2-methoxybenzophenone, and mixtures thereof.

Examples of the thioxanthone initiators may include thioxanthone, 2-methyl thioxanthone, isopropyl thioxanthone, 2,4-diethylthioxanthone, 2,4-diisopropylthioxanthone, 2-chlorothioxanthone, and mixtures thereof.

Examples of the benzoin initiators may include benzoin, benzoin methyl ether, benzoin ethyl ether, benzoin isopropyl ether, benzoin isobutyl ether, benzyl dimethyl ketal, and mixtures thereof.

Examples of the phosphorus initiators may include bisbenzoylphenyl phosphine oxide, benzoyldiphenyl phosphine oxide, and mixtures thereof.

Examples of the oxime initiators may include 2-(o-benzoyloxime)-1-[4-(phenylthio)phenyl]-1,2-octanedione, 1-(o-acetyloxime)-1-[9-ethyl-6-(2-methylbenzoyl)-9H-carb azole-3-yl]ethanone, and mixtures thereof.

The initiator may be present, in terms of solid content, in an amount of about 0.1 parts by weight to about 20 part by weight, preferably about 0.5 parts by weight to about 10 parts by weight based on 100 parts by weight of (A)+(B). Within this range, the photocurable composition allows sufficient photopolymerization and can prevent deterioration in transmittance due to the unreacted initiator remaining after photopolymerization.

The photocurable composition may include, in terms of solid content, about 85 wt % to about 99.9 wt % of (A), about 0.01 wt % to about 5 wt % of (B), and about 0.01 wt % to about 10 wt % of (C). Within this range, it is possible to easily identify whether the composition is formed in a desired pattern after curing, and to increase curing rate of the composition, thereby reducing outgassing.

The photocurable composition may be formed by mixing the photocurable monomer, the luminescent material, and the initiator. Preferably, the photocurable composition is formed as a solvent-free photocurable composition.

As such, the photocurable composition includes the luminescent material, whereby it is possible to easily identify whether the photocurable composition is formed in a desired pattern after curing. Particularly, when the photocurable composition is formed on one surface of an organic light emitting device by deposition or the like and then subjected to curing to form an organic protective layer of the organic light emitting device, it is possible to determine whether the organic protective layer is formed at a desired pattern position through irradiation at a wavelength of 300 nm to 480 nm, thereby allowing easy identification as to defects of the organic protective layer of the organic light emitting device.

In some embodiments, a method of identifying pattern defects of an organic light emitting device may include using the photocurable composition. For example, the method may include depositing the photocurable composition on a substrate on which a plurality of organic light emitting devices are placed in a pattern, curing the photocurable composition, irradiating the cured composition with light at a wavelength of about 300 nm to about 480 nm, and determining whether luminescence occurs between the adjacent organic light emitting devices. When luminescence occurs between adjacent organic light emitting devices, the organic light emitting devices are determined to be defective, whereas when luminescence does not occur between the adjacent organic light emitting devices, the organic light emitting devices are determined not to be defective.

The photocurable composition may have a viscosity of about 5 cPs to about 100 cPs as measured at 25° C. Within this range, the composition can be easily transferred by deposition or the like.

The photocurable composition may have a photocuring rate of about 88.5% to about 100%. Within this range, the composition can realize a layer which does not suffer from a shift by virtue of low shrinkage stress after curing and thus can be used for encapsulation of a device.

A cured product of the photocurable composition may have a transmittance of about 10% to about 100%, for example, about 20% to about 95%, as measured at a wavelength of 350 nm to 480 nm. Within this range, the composition can increase visibility of the luminescent material upon light irradiation and be used for encapsulation of an organic light emitting device.

A cured product of the photocurable composition may have an adhesive strength (die shear strength) to an inorganic protective layer of higher than or equal to 6.4 kgf/(mm)², for example, about 6.4 kgf/(mm)² to about 10 kgf/(mm)². Within this range, the composition can be used for encapsulation of an organic light emitting device.

A member for an apparatus, particularly a member for displays, can suffer from degradation or deterioration in quality due to permeation of gas or liquid in a surrounding environment, for example, atmospheric oxygen, moisture and/or water vapor, and due to permeation of chemicals used in the preparation of electronic products. To prevent this problem, the member for an apparatus needs to be sealed or encapsulated.

Examples of the member for an apparatus may include organic light emitting devices (OLEDs), illumination devices, flexible organic light emitting devices, metal sensor pads, microdisc lasers, electrochromic devices, photochromic devices, microelectromechanical systems, solar cells, integrated circuits, charge coupled devices, light emitting polymers, and light emitting diodes, without being limited thereto.

The photocurable composition according to the present invention may form an organic barrier layer used for sealing or encapsulation of the member for an apparatus, particularly an organic light emitting device or a flexible organic light emitting device.

The barrier layer according to the present invention is an organic barrier layer and may have an outgassing amount of about 0 ppm or more to about 1000 ppm or less. Within this range, the barrier layer can have insignificant adverse effect on the member for an apparatus and extend lifespan of the member for an apparatus. For example, the barrier layer may have an outgassing amount of about 0 ppm or more about 400 ppm or less. For example, the barrier layer may have an outgassing amount of about 10 ppm to about 400 ppm.

The barrier layer according to the present invention is an organic barrier layer and may have an adhesive strength to an inorganic barrier layer of about 6.4 kgf/(mm)² or higher. If the adhesive strength is less than 6.4 kgf/(mm)², external moisture or oxygen can easily permeate between the barrier layers, thereby causing deterioration in reliability. The inorganic barrier layer may include an inorganic barrier layer to be described below (for example, silicon oxides including SiOₓ and the like, silicon nitrides including SiNₓ and the like, and Al₂O₃), without being limited thereto. For example, the organic barrier may have an adhesive strength to an inorganic barrier layer of about 6.4 kgf/(mm)² to about 100 kgf/(mm)², for example, about 6.4 kgf/(mm)² to about 10 kgf/(mm)².

The organic barrier layer may include a cured product of the photocurable composition.

In some embodiments, the organic barrier layer may be formed by photocuring the photocurable composition. The organic barrier layer may be formed by coating the photocurable composition to a thickness of about 0.1 μm to about 20 μm, preferably about 1 μm to about 10 μm, followed by irradiation at about 10 mW/cm² to about 500 mW/cm² for 1 to 50 seconds.

Since the organic barrier layer has a water vapor permeability and an outgassing amount in the range as set forth above, the organic barrier layer and an inorganic barrier layer described below can form a barrier stack for encapsulation of the member for an apparatus.

In accordance with another aspect of the present invention, a barrier stack may include an organic barrier layer and an inorganic barrier layer.

The inorganic barrier layer includes different components from those of the organic barrier layer, thereby supplementing the effects of the organic barrier layer.

The inorganic barrier layer may be any inorganic barrier layer so long as the inorganic barrier layer can exhibit excellent light transmittance and excellent moisture and/or oxygen barrier properties.

For example, the inorganic barrier layer may be formed of metals, nonmetals, compounds of metals or nonmetals, alloys of metals or nonmetals, oxides of metals or nonmetals, fluorides of metals or nonmetals, nitrides of metals or nonmetals, carbides of metals or nonmetals, oxynitrides of metals or nonmetals, borides of metals or nonmetals, oxyborides of metals or nonmetals, silicides of metals or nonmetals, or combinations thereof.

In some embodiments, the metals or the nonmetals may include silicon (Si), aluminum (Al), selenium (Se), zinc (Zn), antimony (Sb), indium (In), germanium (Ge), tin (Sn), bismuth (Bi), transition metals, and lanthanide metals, without being limited thereto.

Specifically, the inorganic barrier layer may be formed of silicon oxides, silicon nitrides, silicon oxynitrides, ZnSe, ZnO, Sb₂O₃, Al₂O₃, In₂O₃, or SnO₂.

The organic barrier layer can secure the aforementioned water vapor permeability and outgassing amount. As a result, when the organic and inorganic barrier layers are alternately deposited, the inorganic barrier layer can secure smoothness. In addition, the organic barrier layer can prevent defects of one inorganic barrier layer from spreading to other inorganic barrier layers.

The organic barrier layer may include a cured product of the photocurable composition.

The barrier stack may include any number of organic and inorganic barrier layers. Combination of the organic and inorganic barrier layers may vary with a level of permeation resistance to oxygen and/or moisture and/or water vapor and/or chemicals.

In the barrier stack, the organic and inorganic barrier layers may be alternately deposited. This is because the aforementioned composition has an effect on the organic barrier layer due to the properties thereof. As a result, the organic and inorganic barrier layers can supplement or reinforce encapsulation of the member for an apparatus. For example, the organic and inorganic layers may be alternately formed in two or more layers, respectively. In addition, the organic and inorganic layers are formed in a total of about 10 layers or less (for example, about 2 layers to about 10 layers), for example, in a total of about 7 layers or less (for example, about 2 layers to about 7 layers).

In the barrier stack, one organic barrier layer may have a thickness of about 0.1 μm to about 20 μm, for example, about 1 μm to about 10 μm, and one inorganic barrier layer may have a thickness of about 5 nm to about 500 nm, for example, about 5 nm to about 50 nm.

The barrier stack is a thin film encapsulant and may have an encapsulation thickness of about more than 0 to about 5 μm or less, for example, from about 1.5 μm to about 5 μm.

The inorganic barrier layer may be formed by a vacuum process, for example, sputtering, chemical vapor deposition, plasma chemical vapor deposition, evaporation, sublimation, electron cyclotron resonance-plasma enhanced chemical vapor deposition, or combinations thereof.

The organic barrier layer may be deposited using the same method as in the inorganic barrier layer, or be formed by coating the photocurable composition, followed by curing.

In accordance with a further aspect of the present invention, an encapsulated apparatus may include a member for the apparatus and a barrier stack formed on the member for the apparatus and including an inorganic barrier layer and an organic barrier layer, wherein the organic barrier layer may include a cured product of the photocurable composition as set forth above.

The organic barrier layer may refer to an encapsulation layer protecting the member for the apparatus including organic electroluminescent devices, organic solar cells, and the like. The organic barrier layer can prevent the member for the apparatus from suffering from degradation or oxidation due to moisture, oxygen, and the like in a surrounding environment. In addition, the organic barrier layer exhibits considerably low outgassing even under high-humidity or high-temperature and high-humidity conditions, and thus minimizes effects of outgassing on the member for the apparatus, thereby preventing performance deterioration and reduction in lifespan of the member for the apparatus.

The organic barrier layer may be formed on an upper or lower side of the inorganic barrier layer.

The inorganic barrier layer may refer to an encapsulation layer protecting the member for the apparatus including organic electroluminescent diodes, organic solar cells, and the like. The inorganic barrier layer may adjoin the member for the apparatus to encapsulate a device, or may encapsulate an internal space containing the member for the apparatus without adjoining the member for the apparatus. The inorganic barrier layer can interrupt contact between external oxygen or moisture and a device, thereby preventing degradation or damage of the member for the apparatus.

The inorganic barrier layer may be formed on an upper side of the member for the apparatus, an upper side of the organic barrier layer, or a lower side of the organic barrier layer.

The encapsulated apparatus include a device encapsulated by the inorganic and organic barrier layers exhibiting different properties. At least one of the inorganic and organic barrier layers may be coupled to a substrate to encapsulate the device.

Each of the inorganic and organic barrier layers may be included in multiple layers such as two layers or more in the encapsulated apparatus. In one embodiment, the inorganic and organic barrier layers may be deposited alternately, for example, in order of inorganic barrier layer/organic barrier layer/inorganic barrier layer/organic barrier layer. Preferably, the inorganic and organic barrier layers are included in a total of about 10 layers or less (for example, about 2 layers to about 10 layers), more preferably in a total of about 7 layers or less (for example, about 2 layers to about 7 layers).

Details of the organic and inorganic barrier layers are as described above.

The encapsulated apparatus may include a substrate depending upon the kind of the member for the apparatus.

The substrate is not particularly restricted so long as the member for the apparatus can be stacked on the substrate. For example, the substrate may be formed of a material such as transparent glass, a plastic sheet, silicon, or metal.

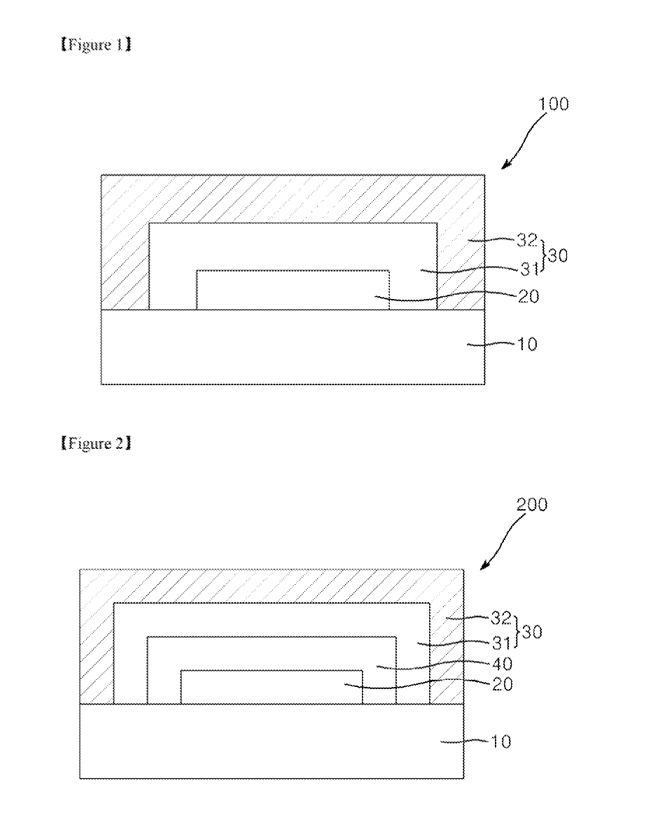

FIG. 1 is a sectional view of an encapsulated apparatus according to one embodiment of the present invention. Referring to FIG. 1, the encapsulated apparatus 100 includes a substrate 10, a member for the apparatus 20 formed on the substrate 10, and a barrier stack 30 formed on the member for the apparatus 20 and including an inorganic barrier layer 31 and an organic barrier layer 32, wherein the inorganic barrier layer 31 adjoins the member for the apparatus 20.

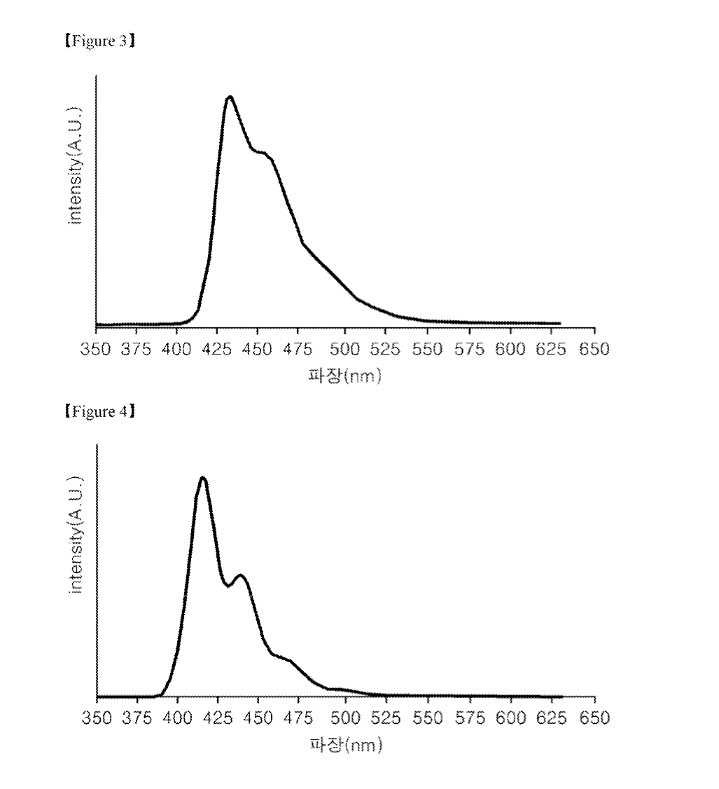

FIG. 2 is a sectional view of an encapsulated apparatus according to another embodiment of the present invention. Referring to FIG. 2, the encapsulated apparatus 200 includes a substrate 10, a member for the apparatus 20 formed on the substrate 10, and a barrier stack 30 formed on the member for the apparatus 20 and including an inorganic barrier layer 31 and an organic barrier layer 32, wherein the inorganic barrier layer 31 may encapsulate an internal space 40 containing the member for the apparatus 20.

Although each of the inorganic and organic barrier layers is illustrated as being formed as a single layer in FIGS. 1 and 2, but, each of the inorganic and organic barrier layers may be formed more than one. In addition, the apparatus may further include a sealant and/or a substrate on a lateral side and/or an upper side of the complex barrier layer composed of the inorganic and organic barrier layers (not shown in FIGS. 1 and 2).

The encapsulated apparatus may be prepared by any typical method. The member for the apparatus is formed on the substrate, followed by forming the inorganic barrier layer on the member for the apparatus. The photocurable composition is coated to a thickness of 1 μm to 5 μm by spin coating, slit coating, or the like, followed by irradiation to form the organic barrier layer. The procedure of forming the inorganic and organic barrier layers may be repeated (preferably 10 times or less).

In some embodiments, the encapsulated apparatus may include an organic electroluminescent display including an organic electroluminescent diode, a display such as a liquid crystal display, a solar cell, and the like, without being limited thereto.

### MODE FOR INVENTION

Hereinafter, the present invention will be described in more detail with reference to some examples. However, it should be understood that these examples are provided for illustration only and are not to be in any way construed as limiting the present invention.

Details of components used in Examples and Comparative Examples are as follows:

(A) Photocurable monomer: (A1) Hexyl acrylate, (A2) Hexanediol diacrylate, (A3) Pentaerythritol tetraacrylate (Aldrich Chemical)

(B) Luminescent material: (B1) Compound represented by Formula 1-33 (3B Scientific Corporation Product List, C.I. Number: C.I. FBA 135), (B2) Compound represented by Formula 2-2 (9-Anthracene methanol, Acros Organics), (B3) Compound represented by Formula 2-3 (9-Anthracenylmethyl methacrylate, Aldrich), (B4) Compound represented by Formula 2-5 (9,10-Diphenyl Anthracene, Aldrich)

(C) Initiator: Darocur TPO (BASF Co., Ltd.)

### Examples 1 to 4 and Comparative Example 1

In a 125 ml brown polypropylene bottle, (A) the photocurable monomer, (B) the luminescent material, and (C) the initiator were placed in amounts as listed in Table 2 (unit: parts by weight), followed by mixing for 3 hours using a shaker, thereby preparing compositions of Examples and Comparative Examples.

Each of the compositions prepared in Examples and Comparative Examples was evaluated as to the following properties. Results are shown in Table 2.

Evaluation of Properties

1. Outgassing amount (ppm): The photocurable composition was spray-coated onto a glass substrate, followed by UV curing through UV irradiation at 100 mW/cm², thereby obtaining an organic barrier layer specimen having a size of 20 cm×20 cm×3 μm (width×length×thickness). Outgassing amount was measured on the specimen using a GC/MS tester (Perkin Elmer Clarus 600). GC/MS utilized a DB-5MS column (length: 30 m, diameter: 0.25 mm, thickness of stationary phase: 0.25 μm) as a column, and helium gas (flow rate: 1.0 mL/min, average velocity=32 cm/s) as a mobile phase. Further, the split ratio was 20:1, and the specimen was maintained at 40° C. for 3 minutes, heated at a rate of 10° C./min and then maintained at 320° C. for 6 minutes. Outgas was collected under the conditions that a glass size was 20 cm×20 cm, a collection container was a Tedlar bag, collection temperature was 90° C., collection time was 30 minutes, N₂ purging was performed at a flow rate of 300 mL/min, and Tenax GR (5% phenyl methyl polysiloxane) was used as an adsorbent. A calibration curve was plotted using a toluene solution in n-hexane in a concentration of 150 ppm, 400 ppm and 800 ppm as a standard solution, wherein R2 value was 0.9987. The above conditions are summarized in Table 1.

TABLE 1

| Conditions | | Details |
|---|---|---|
| Collection conditions | | Glass size: 20 cm × 20 cm |
| | | Collection container: Tedlar bag |
| | | Collection temperature: 90° C. |
| | | Collection time: 30 min |
| | | N2 purge flow rate: 300 mL/min |
| | | Adsorbent: Tenax GR |
| | | (5% phenyl methyl polysiloxane) |
| Conditions for | | Standard solution: Toluene in n-hexane |
| plotting calibration | | Concentration range (reference): |
| curve | | 150 ppm, 400 ppm, 800 ppm |
| | | R2: 0.9987 |
| GC/MS | Column | DB-5MS→30 m × 0.25 mm × 0.25 μm |
| conditions | | (5% phenyl methyl polysiloxane) |
| | Mobile | He |
| | phase | |
| | Flow | 1.0 mL/min (Average velocity = 32 cm/s) |
| | Split | Split ratio = 20:1 |
| | Method | 40° C. (3 min) → 10° C./min → 320° C. (6 min) |

2. Photocuring rate (%): The photocurable composition was measured as to intensity of absorption peaks in the vicinity of 1635 cm⁻¹ (C═C) and 1720 cm⁻¹ (C═O) using an FT-IR spectrometer (NICOLET 4700, Thermo Co., Ltd.). The photocurable composition was spray-coated onto a glass substrate, followed by UV curing through UV irradiation at 100 J/cm² for 10 seconds, thereby obtaining a specimen having a size of 20 cm×20 cm×3 μm (width×length×thickness). Then, the cured film was aliquoted, and the intensity of absorption peaks of the cured film was measured in the vicinity of 1635 cm⁻¹ (C═C) and 1720 cm⁻¹ (C═O) using an FT-IR spectrometer (NICOLET 4700, Thermo Co., Ltd.). Photocuring rate was calculated by Equation 1:

Photocuring rate (%)=|1−(A/B)|×100 (1)

(wherein A is a ratio of the intensity of an absorption peak in the vicinity of 1635 cm⁻¹ to the intensity of an absorption peak in the vicinity of 1720 cm⁻¹ measured for the cured film, and B is a ratio of the intensity of an absorption peak in the vicinity of 1635 cm⁻¹ to the intensity of an absorption peak in the vicinity of 1720 cm⁻¹ measured for the photocurable composition).

3. Adhesive strength (die shear strength, kgf/(mm)²): To measure adhesive strength, 0.01 g of each of the photocurable compositions listed in Table 2 was coated onto a glass substrate having a size of 5 mm×5 mm×2 mm (width×length×height). A glass substrate having a size of 20 mm×80 mm×2 mm (width×length×height) was stacked on the photocurable composition coating layer, followed by curing by exposure to light at a radiant exposure of 1000 J/cm² using a D-bulb light source. For the cured product, die shear strength was measured using a Dage 4000 bond tester.

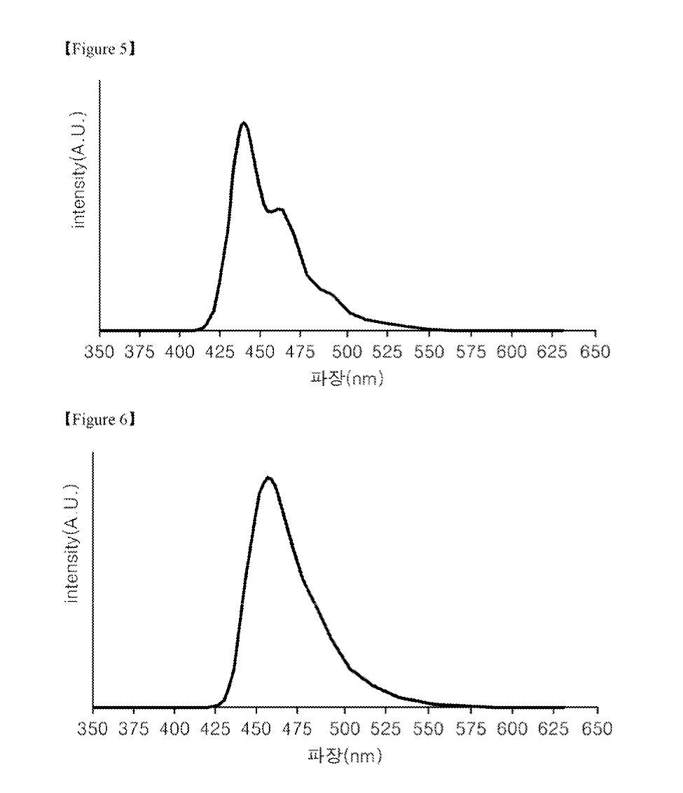

4. Luminescence analysis: A glass substrate with the cured photocurable composition was cut into a specimen having a size of 30 mm×30 mm (width×length). Luminescence wavelength (maximum wavelength, λ max) and luminescence intensity were measured on the specimen using a xenon lamp (F4500, Hitachi Chemical Co., Ltd.). FIGS. 3 to 6 show results of luminescence analysis for Examples 1 to 4, respectively.

5. Identification as to pattern defect with the naked eye: A polyethylene terephthalate (PET) film having a size of 5 cm×5 cm (width×length) was centrally attached on a circular transparent bare glass having a size of 10 cm×10 cm (width×length), followed by coating each of the photocurable compositions of Examples 1 to 4 and Comparative Example 1 to a thickness of 3 μm using a spin-coater (K-Spin8, KDNS Co., Ltd.). After exposure to light at a power output of 100 mJ using an exposer (I10C, Nikon Inc.), the PET film was detached. Both a part which has been occupied by the PET film and thus does not have the photocurable composition and a part which has not been occupied by the PET film and thus has the photocurable composition were subjected to light irradiation using a xenon lamp (F4500, Hitachi Chemical Co., Ltd.), followed by identification as to pattern defects using a microscope (E200, Nikon Inc.). The specimen was rated as ◯ when the part having no photocurable composition and the part having the photocurable composition can be easily distinguished from each other with the naked eye, whereas the specimen was rated as X when the part having no photocurable composition and the part having the photocurable composition cannot easily be distinguished from each other with the naked eye.

TABLE 2

| | | | | | | Comparative |
|---|---|---|---|---|---|---|
| | | Example | | | | Example |
| | | 1 | 2 | 3 | 4 | 1 |
| A | A1 | 15 | 15 | 15 | 15 | 15 |
| | A2 | 74.8 | 74.8 | 74.8 | 74.8 | 75 |
| | A3 | 10 | 10 | 10 | 10 | 10 |
| B | B1 | 0.2 | — | — | — | — |
| | B2 | — | 0.2 | — | — | — |
| | B3 | — | — | 0.2 | — | — |
| | B4 | — | — | — | 0.2 | — |
| C | | 5 | 5 | 5 | 5 | 5 |
| Outgassing amount | | 352 | 347 | 350 | 340 | 345 |
| (ppm) | | | | | | |
| Photocuring rate (%) | | 89.1 | 88.8 | 88.7 | 89.2 | 88.3 |
| Adhesive strength | | 6.4 | 6.5 | 6.5 | 6.5 | 6.5 |
| (kgf/(mm)²) | | | | | | |
| Luminescence | λmax | 430 | 415 | 440 | 455 | — |
| Analysis | (nm) | | | | | |
| | Graph | FIG. | FIG. | FIG. 5 | FIG. 6 | — |
| | | 3 | 4 | | | |

| | | | | | |
|---|---|---|---|---|---|
| Identification with | ◯ | ◯ | ◯ | ◯ | X |
| the naked eye | | | | | |

As shown in Table 2, it could be seen that the coating films formed of the photocurable compositions according to the present invention had comparable properties to the coating film formed of the composition in Comparative Example 1 in terms of outgassing amount, photocuring rate, and adhesive strength. In addition, referring to FIGS. 3 to 6, the coating films formed of the photocurable compositions according to the present invention fluoresced at a wavelength of 400 nm to 500 nm upon UV irradiation, thereby allowing easy identification as to pattern defects with the naked eye, as shown in Table 2.

On the contrary, it could be seen that although the coating film formed of the composition in Comparative Example 1 not including the luminescent material could secure sufficient properties in terms of outgassing amount, photocuring rate, and adhesive strength, the composition did not allow easy identification as to pattern defects with the naked eye.

Although some embodiments have been described herein, it should be understood by those skilled in the art that these embodiments are given by way of illustration only and the present invention is not limited thereto. In addition, it should be understood that various modifications, variations, and alterations can be made by those skilled in the art without departing from the spirit and scope of the present invention. Therefore, the scope of the invention should be limited only by the accompanying claims and equivalents thereof.

1. A photocurable composition comprising:
a photocurable monomer;
a luminescent material, the luminescent material having an emission maximum wavelength of about 400 nm to about 500 nm upon irradiation by light having a wavelength in a range of 300 nm to 480 nm; and
an initiator.

2. The photocurable composition according to claim 1, wherein the luminescent material includes one or more of:
an organic fluorescent dye, the organic fluorescent dye having a C.I. Number (color index number) of C.I. Fluorescent Brightening Agents 1 to 393,
a substituted or unsubstituted C₁₀ to C₃₀ aromatic hydrocarbon, or
a substituted or unsubstituted C₆ to C₃₀ hetero aromatic hydrocarbon.

3. The photocurable composition according to claim 2, wherein the luminescent material includes a substituted or unsubstituted C₁₀ to C₃₀ aromatic hydrocarbon represented by Formula 2: 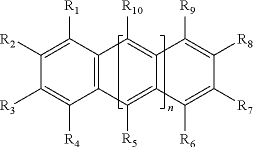
wherein, in Formula 2,
n is an integer from 1 to 6,
R₁, R₂, R₃, R₄, R₅, R₆, R₇, R₈, R₉, and R₁₀ are each independently hydrogen, a C₁ to C₁₀ alkyl group, a C₆ to C₁₀ aryl group, an amine group, a halogen, a cyano group, a nitro group, Formula 3, Formula 4, Formula 5, or a hydroxyl group-containing C₁ to C₁₀ alkyl group, 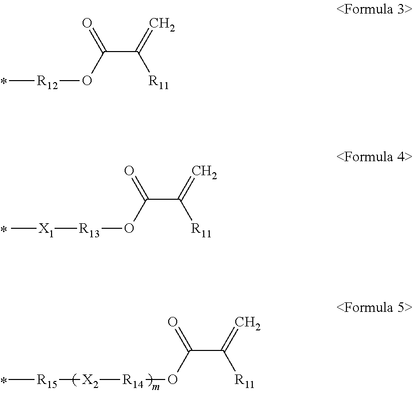
wherein, in Formulas 3 to 5,
* is a binding site to aromatic carbon in Formula 2,
R₁₁ is hydrogen or a C₁ to C₅ alkyl group,
R₁₂ is a single bond, a C₁ to C₁₀ alkylene group, or a C₆ to C₂₀ arylene group,
R₁₃, R₁₄, and R₁₅ are the same or different and are each independently a C₁ to C₁₀ alkylene group or a C₆ to C₂₀ arylene group,
X₁ and X₂ are the same or different and are each independently O, S, or NR (R being hydrogen or a C₁ to C₅ alkyl group, and
m is an integer from 1 to 6.

4. The photocurable composition according to claim 3, wherein Formula 2 is represented by any one of Formulas 2-1 to 2-6:

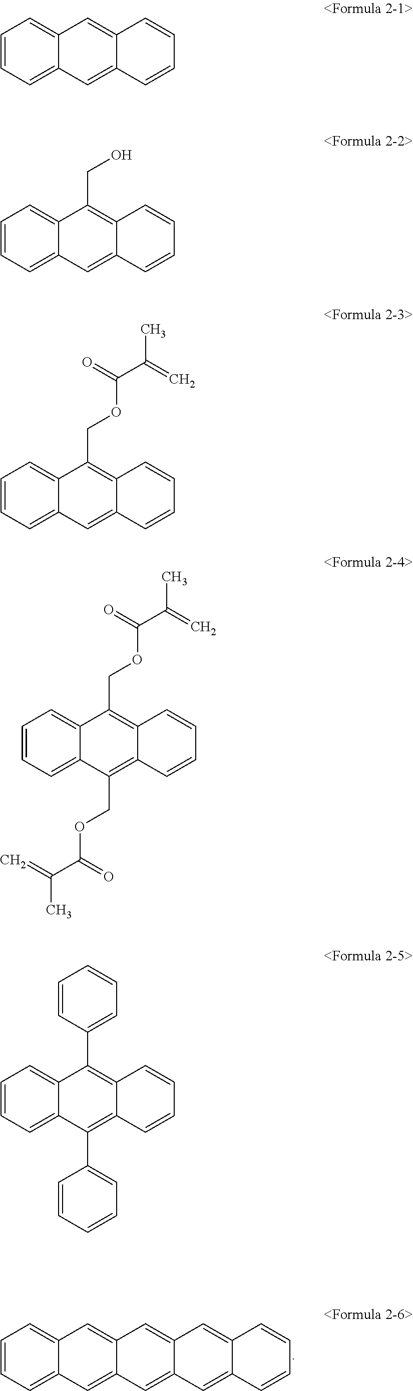

5. The photocurable composition according to claim 1, wherein the luminescent material is present in an amount of about 0.01 wt % to about 5 wt % in the composition in terms of solid content.

6. The photocurable composition according to claim 1, wherein the photocurable monomer includes one or more of a C₁ to C₂₀ alkyl group-containing (meth)acrylate, a di(meth)acrylate of a C₂ to C₂₀ diol, a tri(meth)acrylate of a C₃ to C₂₀ triol, or a tetra(meth)acrylate of a C₄ to C₂₀ tetraol.

7. The photocurable composition according to claim 1, comprising, in terms of solid content, about 85 wt % to about 99.9 wt % of the photocurable monomer, about 0.01 wt % to about 5 wt % of the luminescent material, and about 0.01 wt % to about 10 wt % of the initiator.

8. The photocurable composition according to claim 1,
wherein the photocurable composition is suitable for identifying pattern defects of an organic protective layer of an organic light emitting device.

9. An apparatus, comprising:
a member; and
a barrier stack formed on the member, the barrier stack including an inorganic barrier layer and an organic barrier layer, the organic barrier layer including a cured product of the photocurable composition according to claim 1.

10. The apparatus according to claim 9, wherein the inorganic barrier layer includes one or more of a metal, a nonmetal, a compound of a metal or nonmetal, an alloy of a metal or nonmetal, an oxide of a metal or nonmetal, a fluoride of a metal or nonmetal, a nitride of a metal or nonmetal, a carbide of a metal or nonmetal, an oxynitride of a metal or nonmetal, a boride of a metal or nonmetal, an oxyboride of a metal or nonmetal, or a silicide of a metal or nonmetal, wherein the metals and nonmetals include one or more of silicon, aluminum, selenium, zinc, antimony, indium, germanium, tin, bismuth, a transition metal, or a lanthanide metal.

11. The apparatus according to claim 9, wherein, in the barrier stack, the organic barrier layer and the inorganic barrier layer repeatedly alternate.

12. The apparatus according to claim 9, wherein the member includes one or more of a flexible organic light emitting device, an organic light emitting device, an illumination device, a metal sensor pad, a microdisc laser, an electrochromic device, a photochromic device, a microelectromechanical system, a solar cell, an integrated circuit, a charge coupled device, a light emitting polymer, or a light emitting diode.

13. An organic light emitting diode display, comprising:
an organic light emitting diode; and
an encapsulation layer covering the organic light emitting diode, the encapsulation layer including a stack of alternating inorganic and organic layers, at least one organic layer emitting light at a wavelength in a range of about 400 nm to about 500 nm when irradiated with light having a wavelength in a range of 300 nm to 480 nm.

14. The organic light emitting diode display according to claim 13, wherein, when the at least one organic layer is irradiated with light having a wavelength in a range of 300 nm to 480 nm, light emitted by the at least one organic layer has maximum intensity in the wavelength range of about 400 nm to about 500 nm.

15. A method of fabricating a display device, the method comprising:
forming a light emitting element; and
encapsulating the light emitting element with a stack of alternating inorganic and organic layers, at least one organic layer being formed using the photocurable composition according to claim 1.
